(19) United States
(12) Patent Application Publication
(10) Pub. No.: US 2010/0202113 A1
(43) Pub. Date: Aug. 12, 2010

(54) COMMODITY SALE DATA PROCESSING APPARATUS

(75) Inventor: Kazuhiro Fushimi, Shizuoka (JP)

Correspondence Address: TUROCY & WATSON, LLP, 127 Public Square, 57th Floor, Key Tower, CLEVELAND, OH, 44114, US

(73) Assignee: TOSHIBA TEC KABUSHIKI KAISHA, Tokyo (JP)

(21) Appl. No.: 12/701,738

(22) Filed: Feb. 8, 2010

(30) Foreign Application Priority Data
Feb. 12, 2009 (JP) 2009-030249

(51) Int. Cl. H05K 5/00

(52) U.S. Cl. 361/724

(57) ABSTRACT

A commodity sale data processing apparatus includes: a casing; a power switch provided on a predetermined panel surface of the casing and adapted for starting up a power source; a cover which can freely open and close by turning between an open position and a closed position with respect to the predetermined panel surface where the power switch is provided; a switch hole which is provided as a part of the cover at a position facing the power switch cut out in a state where the cover is situated at the closed position, and through which the power switch is exposed outside; and a switch hole cover which covers the exposure of the power switch in a state of being attached to the switch hole.

### CROSS-REFERENCE TO RELATED APPLICATION

This application is based upon and claims the benefit of priority from Japanese Patent Application 2009-030249 filed on Feb. 12, 2009, the entire contents of which are incorporated herein by reference.

### TECHNICAL FIELD

The present invention relates to a commodity sale data processing apparatus.

### BACKGROUND

A commodity sale data processing apparatus such as an ECR or POS terminal has components such as a hardware component which functions for commodity sale data processing, a keyboard, a display, and a printer. The commodity sale data processing apparatus simultaneously starts up the power source for each of these components by manual operation of a power switch installed in a casing unit or by a signal via a network.

Meanwhile, JP-A-2006-92703 discloses a POS terminal provided with a front cover which can freely open and close with respect to a front panel of a casing unit where a power switch is provided. Such a front cover opens and closes at the time of performing maintenance of a control section and an HDD unit installed in the casing unit.

Therefore, in the POS terminal disclosed in JP-A-2006-92703, it is not possible to operate the power switch without opening the front cover.

By the way, in terms of the startup of a POS system, the status of the power switch differs depending on the user's application.

One user may demand that, since the power switch is operated daily and there are many operators, the power switch should not be covered with a cover and should be exposed on the surface of the casing so that the location of the power switch can be confirmed and the power switch can be operated immediately. Another user may demand that though the operation of the power switch is basically not carried out since the power is turned on and off via a network, the power switch should be covered with a cover so as not to be operated erroneously by an operator, and the operation of the power switch should be enabled in case of emergency.

If individual structures are provided to cope with the demands stemming from such diverse conditions of use, the product machine types increase and management of manufacturing and stocks become complex. Therefore, a shared structure that can easily meet these demands is needed.

### SUMMARY

In view of the foregoing, it is an object of the invention to provide a commodity sale data processing apparatus which can easily cope with change in application with respect to the operation of the power switch without increasing product types.

A commodity sale data processing apparatus according to an aspect of the invention includes: a casing; a power switch provided on a predetermined panel surface of the casing and adapted for starting up a power source; a cover which can freely open and close by turning between an open position and a closed position with respect to the predetermined panel surface where the power switch is provided; a switch hole which is provided as a part of the cover at a position facing the power switch cut out in a state where the cover is situated at the closed position, and through which the power switch is exposed outside; and a switch hole cover which covers the exposure of the power switch in a state of being attached to the switch hole.

### DESCRIPTION OF THE DRAWINGS

FIG. 1 is a perspective view showing the appearance of a POS terminal according to an embodiment of the invention.

FIG. 2 is a perspective view showing the appearance of the POS terminal in the state where a front cover is opened.

FIG. 3 is an enlarged perspective view showing a part of the front cover.

FIG. 4 is an enlarged perspective view showing a part of the front cover in which a switch hole cover is fitted.

### DETAILED DESCRIPTION

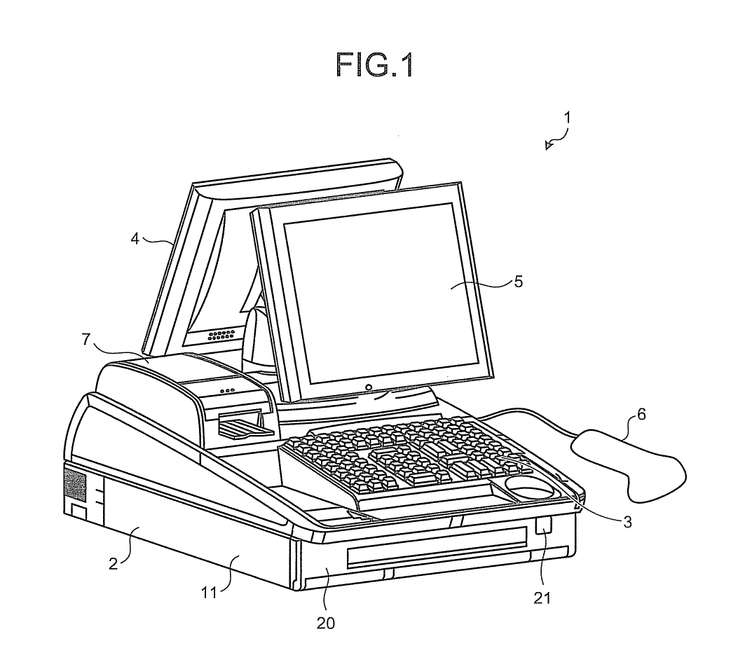

An embodiment of the invention will be described with reference to FIG. 1 to FIG. 4. This embodiment is an example where a POS (point of sales) terminal is used as a commodity sale data processing apparatus.

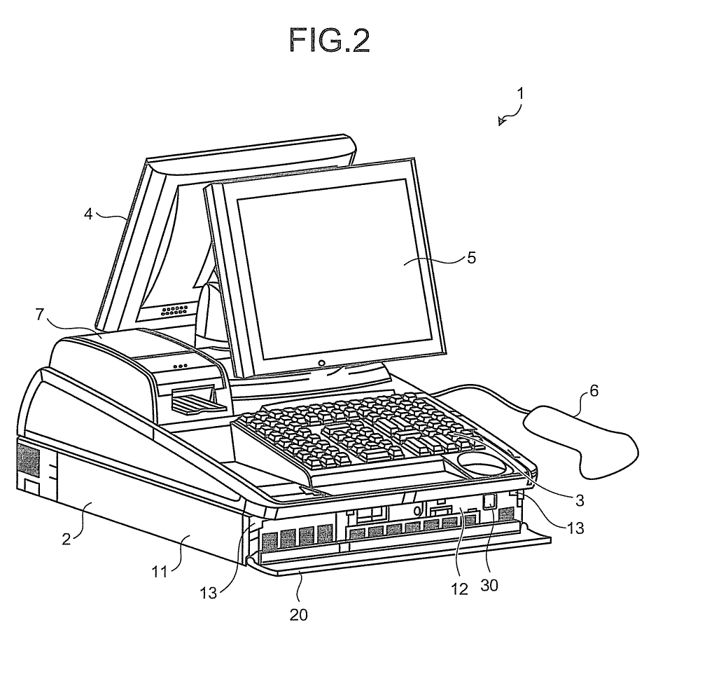

Here, FIG. 1 is a perspective view showing the appearance of a POS terminal 1 according to the embodiment of the invention. FIG. 2 is a perspective view showing the appearance of the POS terminal 1 in the state where a front cover 20 is opened. As shown in FIG. 1 and FIG. 2, in the POS terminal 1, a keyboard 3, a customer display device 4, a cashier display device 5, a barcode scanner 6, a thermal printer 7 and the like are connected to a control unit 2 as an apparatus body.

The control unit 2 has a control section and an HDD (hard disk drive) unit, not shown, which are installed inside and drive-control each unit. The control section mainly includes a CPU (central processing unit) which centrally controls each unit. To the control section, the keyboard 3, the customer display device 4, the cashier display device 5, the barcode scanner 6 and the thermal printer 7 are connected via an input-output port, not shown.

As shown in FIG. 1 and FIG. 2, the control unit 2 has a rectangular parallelepiped-shaped casing 11. In the casing 11, the keyboard 3, the cashier display device 5, the customer display device 4 and the thermal printer 7 are loaded. The casing 11 has within itself the above-described control section, the HDD unit and so on. The casing 11 has, on its front side, the front cover 20 to which a magnet receiver (not shown) made of iron to receive a magnet 13, which will be described later, is attached. The front cover 20 opens and closes at the time of carrying out maintenance of the control section, the HDD unit and so on installed in the control unit 2. Of the casing 11 of the control unit 2, the surface where the keyboard 3 or the like is loaded is referred to as a loading surface, and the surface placed on a drawer, not shown, or the like, is referred to as a placing surface.

In the control unit 2, the front cover 20 situated on the operator side of the casing 11 is provided on a shaft, rotatably with respect to a front panel 12 on the placing surface side of the casing 11. In the control unit 2, the magnet 13 is arranged to the loading surface side of the casing 11, on the front panel 12. With such a configuration, if the loading surface side of the casing 11 on the front cover 20 is pulled, the magnet receiver of the front cover 20 is released from the magnet 13 on the front panel 12, and thus opening and closing about the shaft on the placing surface side of the casing 11 on the front cover 20 are performed. Therefore, the front cover 20 turns between the open position and the closed position and becomes able to freely open and close with respect to the front panel 12 of the casing 11.

As shown in FIG. 2, the control unit 2 has, on the front panel 12 of the casing 11, a power switch 30 for simultaneously starting up the power source for the components including the control unit 2, the keyboard 3, the customer display device 4, the cashier display device 5, the barcode scanner 6, and the thermal printer 7.

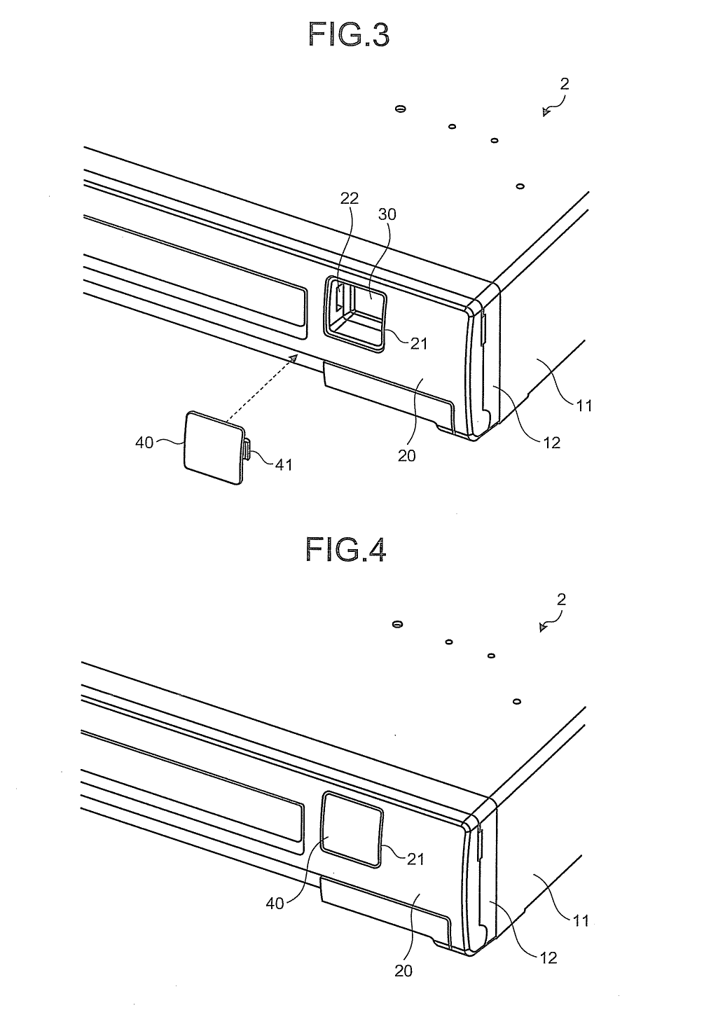

FIG. 3 is an enlarged perspective view showing a part of the front cover 20. As shown in FIG. 3, the control unit 2 has, on the front cover 20, a switch hole 21 through which the power switch 30 is exposed outside. The switch hole 21 is formed by a cut-out at a position facing the power switch 30 in the state where the front cover is situated at the closed position with respect to the front panel 12 of the casing 11. With such a configuration, even in the state where the front cover 20 is closed to the front panel 12 of the casing 11, the position of the power switch 30 can be confirmed and the operator can operate the power switch 30. That is, the operator does not have to open and close the front cover 20 every time the operator operates the power switch.

Moreover, as shown in FIG. 3, the POS terminal 1 has a switch hole cover 40 attachable to and removable from the switch hole 21. The switch hole cover 40 is made of a resin and attachable to and removable from the switch hole 21 from outside by so-called snap-fitting. More specifically, a pair of fastening parts 41 is formed on sides opposite to each other of the switch hole cover 40. As the switch hole cover 40 is fitted in the switch hole 21, the fastening parts 41 of the switch hole cover 40 act as springs and enter a pair of fastening holes 22, respectively, provided in the switch hole 21. Thus, the switch hole cover 40 is fixed in the switch hole 21.

FIG. 4 is an enlarged perspective view showing a part of the front cover 20 in which the switch hole cover 40 is fitted. As shown in FIG. 4, in the state where the switch hole cover 40 is fixed in the switch hole 21, the exposure of the power switch 30 is covered. The operator cannot confirm the position of the power switch 30 and the operator cannot operate the power switch 30, either. The front cover 20 can freely open and close even in the state where the switch hole cover 40 is fixed in the switch hole 21.

To detach the switch hole cover 40 from the state where the switch hole cover 40 is fixed in the switch hole 21, the fastening parts 41 of the switch hole cover 40 can be pushed from the surface of the front cover 20 on the side of the front panel 12 of the casing 11 and thus can be released from the fastening holes 22.

If the user demands that, since the power switch is operated daily and there are many operators, the power switch should not be covered with a cover and should be exposed on the surface of the casing so that its position can be confirmed and the power switch can be operated immediately, the POS terminal 1 is in the state where the switch hole cover 40 is not fitted in the switch hole 21. If the user demands that, though the operation of the power switch is basically not carried out since the power is turned on and off via a network, the power switch should be covered with a cover so as to prevent erroneous operation by the operator, and the operation of the power switch should be enabled in case of emergency, the POS terminal 1 is in the state where the switch hole cover 40 is fitted in the switch hole 21.

In this manner, according to the embodiment, there is provided the switch hole 21 through which the power switch 30 is exposed outside in the state where the front cover 20 that can freely open and close with respect to the front panel 12 provided with the power switch 30 is situated at the closed position, and the switch hole cover 40 which is attachable to and removable from the switch hole 21 and covers the exposure of the power switch 30 in the state where the switch hole cover 40 is attached to the switch hole 21. Thus, a user who wishes to confirm the position of the power switch 30 and to easily operate the power switch 30 can use the apparatus in the state where the switch hole cover 40 is not attached to the switch hole 21. Meanwhile, a user who demands that the power switch 30 is usually not exposed outside but can be operated in emergency can use the apparatus in the state where the switch hole cover 40 is attached to the switch hole 21. Depending on the application of the power switch 30, whether to attach the switch hole cover 40 to the switch hole 21 or not to attach the switch hole cover 40 to the switch hole 21 can be selected. Therefore, with the simple structure having an additional small component like the switch hole cover 40, it is possible to easily cope with changes in application in terms of the operation of the power switch 30 without increasing product types.

Further advantages and modifications can easily be thought of by those skilled in the art. Therefore, broader embodiments of the invention should not be limited to the specific details and representative embodiments described above. Thus, various changes and modifications can be made without departing from the spirit and scope of the comprehensive inventive concept defined by the attached claims and their equivalents.

What is claimed is:

1. A commodity sale data processing apparatus comprising:
a casing;
a power switch provided on a predetermined panel surface of the casing and adapted for starting up a power source;
a cover which can freely open and close by turning between an open position and a closed position with respect to the predetermined panel surface where the power switch is provided;
a switch hole which is provided as a part of the cover at a position facing the power switch cut out in a state where the cover is situated at the closed position, and through which the power switch is exposed outside; and
a switch hole cover which covers the exposure of the power switch in a state of being attached to the switch hole.

2. The apparatus of claim 1, wherein the switch hole cover is provided in a manner that the switch hole cover is attachable to and removable from the switch hole.

3. The apparatus of claim 1, wherein the predetermined panel surface where the power switch is provided is a panel situated on an operator side of the casing.

4. The apparatus of claim 2, wherein the switch hole cover is provided in a manner that the switch hole cover is attachable to and removable from the switch hole from outside by snap-fitting.

5. The apparatus of claim 4, wherein the switch hole cover has a pair of fastening parts on sides opposite to each other,
the switch hole has a pair of fastening holes at positions corresponding to the fastening parts, and
as the switch hole cover is fitted in the switch hole, the fastening parts of the switch hole cover act as springs and enter the pair of fastening holes, respectively, provided in the switch hole, and the switch hole cover is thus attached to the switch hole.

6. The apparatus of claim 4, wherein the switch hole cover is made of a resin.

7. The apparatus of claim 1, wherein the cover can freely open and close even in a state where the switch hole cover is attached to the switch hole.

8. The apparatus of claim 1, wherein a magnet is provided on the panel surface,
a magnet receiver made of iron to receive the magnet provided on the panel is provided on the cover, and
as the cover in the closed state is pulled, the magnet receiver on the cover is released from the magnet on the panel surface.

9. The apparatus of claim 1, wherein the cover is opened and closed at the time of carrying out maintenance of a control section in the casing.

10. The apparatus of claim 1, wherein the cover is opened and closed at the time of carrying out maintenance of an HDD (hard disk drive) unit in the casing.
